(19) United States
(12) Patent Application Publication
(10) Pub. No.: US 2025/0270409 A1
(43) Pub. Date: Aug. 28, 2025

(54) ALUMINUM-CONTAINING INHIBITOR COMPOUNDS FOR SELECTIVE DEPOSITION

(71) Applicant: ENTEGRIS, INC., Billerica, MA (US)

(72) Inventors: Thomas M. Cameron, Newtown, CT (US); Drew Michael Hood, Newtown, CT (US)

(21) Appl. No.: 19/060,599

(22) Filed: Feb. 21, 2025

Related U.S. Application Data
(60) Provisional application No. 63/557,297, filed on Feb. 23, 2024.

(51) Int. Cl. C09D 7/63; C23C 16/20

(52) U.S. Cl. CPC C09D 7/63; C23C 16/20

(57) ABSTRACT

Aluminum-containing inhibitor compounds for selective deposition are provided. A method for selective deposition comprises obtaining a substrate having a first surface and a second surface, exposing the substrate to an Al-containing inhibitor to modify the first surface, and selectively depositing a film on the second surface. The aluminum-containing inhibitor compound is a compound comprising a substituted aluminum alkyl. Related systems, related compositions, and related devices, among other things, are further provided.

### CROSS-REFERENCE TO RELATED APPLICATIONS

This application claims the benefit under 35 USC 119 of U.S. Provisional Patent Application No. 63/557,297, filed Feb. 23, 2024, the disclosure of which is hereby incorporated herein by reference in its entirety.

### FIELD

The present disclosure relates to aluminum-containing inhibitor compounds for selective deposition.

### BACKGROUND

Precursors are deposited on surfaces of substrates. During vapor deposition process, the precursors can be undesirably deposited on certain surfaces. When precursors are undesirably deposited on those surfaces, the deposited precursors must be removed therefrom.

### SUMMARY

Some embodiments relate to a method. In some embodiments, the method comprises obtaining a substrate having a first surface and a second surface. In some embodiments, the method comprises exposing the substrate to an Al-containing inhibitor to modify the first surface. In some embodiments, the Al-containing inhibitor is a compound comprising a substituted aluminum alkyl. In some embodiments, the method comprises selectively depositing a film on the second surface.

Some embodiments relate to a composition. In some embodiments, the composition comprises an Al-containing inhibitor comprising a compound of the formula: Q-Al—(R)₂. In some embodiments, Q is a cyclopentadienyl or an indenyl. In some embodiments, R is independently an alkyl. In some embodiments, when the Al-containing inhibitor is exposed to a substrate having a first surface with hydroxyl groups and a second surface without hydroxyl groups, the Al-containing inhibitor modifies the first surface sufficient for a film to be selectively deposited on the second surface.

Some embodiments relate to a device. In some embodiments, the device comprises a film. In some embodiments, the device comprises an Al-containing inhibitor. In some embodiments, the device comprises a substrate having at least a first surface and a second surface. In some embodiments, the Al-containing inhibitor is deposited on the first surface. In some embodiments, the film is not deposited on the first surface. In some embodiments, the film is deposited on the second surface.

### DRAWINGS

FIG. 1 is a flowchart of a method for selective deposition, according to some embodiments.

FIG. 2 is a schematic diagram of a cross-section of a substrate, according to some embodiments.

FIG. 3 is a schematic diagram of a method for selective deposition, according to some embodiments.

### DETAILED DESCRIPTION

As used herein, the term “alkyl” refers to a hydrocarbyl having from 1 to 30 carbon atoms. The alkyl may be attached via a single bond. An alkyl having n carbon atoms may be designated as a “Cₙ alkyl.” For example, a “C₃ alkyl” may include n-propyl and isopropyl.

An alkyl having a range of carbon atoms, such as 1 to 30 carbon atoms, may be designated as a C₁-C₃₀ alkyl. In some embodiments, the alkyl is linear. In some embodiments, the alkyl is branched. In some embodiments, the alkyl is substituted. In some embodiments, the alkyl is unsubstituted. In some embodiments, the alkyl comprises or is selected from the group consisting of at least one of a C₁-C₃₀ alkyl, C₁-C₂₉ alkyl, C₁-C₂₈ alkyl, C₁-C₂₇ alkyl, C₁-C₂₇ alkyl, C₁-C₂₆ alkyl, C₁-C₂₅ alkyl, C₁-C₂₄ alkyl, C₁-C₂₃ alkyl, C₁-C₂₂ alkyl, C₁-C₂₁ alkyl, C₁-C₂₀ alkyl, C₁-C₁₉ alkyl, C₁-C₁₈ alkyl, C₁-C₁₇ alkyl, C₁-C₁₆ alkyl, C₁-C₁₅ alkyl, C₁-C₁₄ alkyl, C₁-C₁₃ alkyl, C₁-C₁₂ alkyl, C₁-C₁₁ alkyl, C₁-C₁₀ alkyl, a C₁-C₉ alkyl, a C₁-C₈ alkyl, a C₁-C₇ alkyl, a C₁-C₆ alkyl, a C₁-C₅ alkyl, a C₁-C₄ alkyl, a C₁-C₃ alkyl, a C₁-C₂ alkyl, a C₂-C₃₀ alkyl, a C₃-C₃₀ alkyl, a C₄-C₃₀ alkyl, a C₅-C₃₀ alkyl, a C₆-C₃₀ alkyl, a C₇-C₃₀ alkyl, a C₈-C₃₀ alkyl, a C₉-C₃₀ alkyl, a C₁₀-C₃₀ alkyl, a C₁₁-C₃₀ alkyl, a C₁₂-C₃₀ alkyl, a C₁₃-C₃₀ alkyl, a C₁₄-C₃₀ alkyl, a C₁₅-C₃₀ alkyl, a C₁₆-C₃₀ alkyl, a C₁₇-C₃₀ alkyl, a C₁₈-C₃₀ alkyl, a C₁₉-C₃₀ alkyl, a C₂₀-C₃₀ alkyl, a C₂₁-C₃₀ alkyl, a C₂₂-C₃₀ alkyl, a C₂₃-C₃₀ alkyl, a C₂₄-C₃₀ alkyl, a C₂₅-C₃₀ alkyl, a C₂-C₃₀ alkyl, a C₂₇-C₃₀ alkyl, a C₂₈-C₃₀ alkyl, a C₂₉-C₃₀ alkyl, a C₂-C₁₀ alkyl, a C₃-C₁₀ alkyl, a C₄-C₁₀ alkyl, a C₅-C₁₀ alkyl, a C₆-C₁₀ alkyl, a C₇-C₁₀ alkyl, a C₅-C₁₀ alkyl, a C₂-C₉ alkyl, a C₂-C₅ alkyl, a C₂-C₇ alkyl, a C₂-C₆ alkyl, a C₂-C₅ alkyl, a C₃-C₅ alkyl, or any combination thereof. In some embodiments, the alkyl comprises or is selected from the group consisting of at least one of methyl, ethyl, n-propyl, 1-methylethyl (iso-propyl), n-butyl, iso-butyl, sec-butyl, n-pentyl, 1,1-dimethylethyl (t-butyl), n-pentyl, iso-pentyl, n-hexyl, isohexyl, 3-methylhexyl, 2-methylhexyl, heptyl, octyl, nonyl, decyl, dodecyl, octadecyl, or any combination thereof. In some embodiments, the term “alkyl” refers generally to alkyls, alkenyls, alkynyls, and/or cycloalkyls.

As used herein, the term “haloalkyl” refers to an alkyl as defined here, wherein at least one of the hydrogen atoms of the alkyl is replaced with a halide as defined herein. In some embodiments, the haloalkyl comprises a fluoroalkyl. In some embodiments, the fluoroalkyl comprises at least one of —CH₂CF₃, —CH(CF₃)₂, —CH₂F, —CH₂CH₂F, —CF₃, —CF₂CF₃, or any combination thereof.

As used herein, the term “metal” refers to at least one of an alkali metal, an alkaline earth metal, a transition metal, a post-transition metal, a lanthanoid, an actinoid, or any combination thereof. In some embodiments, for example, the metal comprises or is selected from the group consisting of a transition metal. In some embodiments, the transition metal comprises or is selected from the group consisting of at least one of scandium (Sc), yttrium (Y), titanium (Ti), zirconium (Zr), hafnium (Hf), vanadium (V), niobium (Nb), tantalum (Ta), chromium (Cr), molybdenum (Mo), tungsten (W), manganese (Mn), technetium (Tc), rhenium (Re), iron (Fe), ruthenium (Ru), osmium (Os), cobalt (Co), rhodium (Rh), iridium (Ir), nickel (Ni), palladium (Pd), platinum (Pt), copper (Cu), silver (Ag), gold (Au), zinc (Zn), cadmium (Cd), mercury (Hg), or any combination thereof. In some embodiments, the metal is in ionic form, elemental form, or any combination thereof.

Some embodiments relate to aluminum-containing (Al-containing) inhibitor compounds for selective deposition processes. In some embodiments, the Al-containing inhibitor compounds provide for deposition of precursors on select surfaces. In some embodiments, for example, the Al-containing inhibitor compounds selectively inhibit a first surface of a substrate, without inhibiting a second surface of the substrate. In some embodiments, when the first surface of the substrate is exposed to a precursor, the precursor is deposited on the second surface. That is, in some embodiments, the precursor is not deposited on the first surface of the substrate which remains inhibited by the Al-containing inhibitor compounds. In some embodiments, the precursor would deposit on the first surface of the substrate in the absence of the Al-containing inhibitor compounds. In some embodiments, the Al-containing inhibitor compounds disclosed herein permit selective area deposition of precursors on select surfaces.

The Al-containing inhibitors disclosed herein may be useful for selective deposition of films on substrates. In some embodiments, a film is selectively deposited on a substrate when a first surface and a second surface of a substrate are exposed to a precursor, the precursor is deposited on the second surface of the substrate (e.g., as a film), and the precursor is not deposited on the first surface of the substrate. In some embodiments, the first surface and the second surface are different (e.g., chemically different). In some embodiments, the precursor is deposited on the second surface with a selectivity over the first surface. In some embodiments, selectively depositing a film on the second surface comprises a process in which the film is not or is not substantially deposited on the first surface. In some embodiments, the precursors are selectively deposited, over a range of thicknesses, on the second surface of the substrate, and not on the first surface of the substrate.

The Al-containing inhibitor compounds inhibitor compounds and related systems and methods disclosed herein may be useful in the fabrication of microelectronic devices, including semiconductor devices, and the like. For example, the Al-containing inhibitor compounds can be used to form films or layers for area selective deposition (ASD) during one or more deposition processes. Examples of deposition processes include, without limitation, at least one of a chemical vapor deposition (CVD) process, a digital or pulsed chemical vapor deposition process, a plasma-enhanced cyclical chemical vapor deposition process (PECCVD), a flowable chemical vapor deposition process (FCVD), an atomic layer deposition (ALD) process, a thermal atomic layer deposition, a plasma-enhanced atomic layer deposition (PEALD) process, a metal organic chemical vapor deposition (MOCVD) process, a plasma-enhanced chemical vapor deposition (PECVD) process, or any combination thereof. The deposition processes may comprise a water-based deposition process, such as, a water-based area selective deposition process.

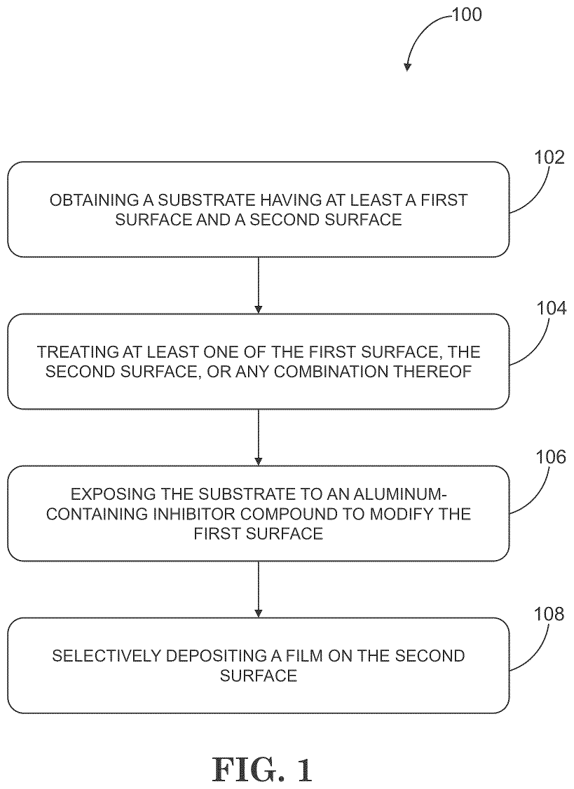

FIG. 1 is a flowchart of a method for selective deposition 100, according to some embodiments. As shown in FIG. 1, in some embodiments, the method for selective deposition 100 comprises one or more of the following steps: obtaining 102 a substrate having at least a first surface and a second surface; treating 104 at least one of the first surface, the second surface, or any combination thereof; exposing 106 the substrate to an Al-containing inhibitor to modify the first surface; and selectively 108 depositing a film on the second surface. In some embodiments, the method for selective deposition does not comprise any one or more of the foregoing steps.

At step 102, the method for selective deposition 100 comprises obtaining a substrate having at least a first surface and a second surface.

The first surface and the second surface may be different. In some embodiments, the first surface is a surface to be inhibited. For example, in some embodiments, the first surface is a surface configured to be inhibited by the Al-containing inhibitor compound. In some embodiments, the first surface is a surface configured to react with the Al-containing inhibitor compound. In some embodiments, when the first surface reacts with the Al-containing inhibitor compound, the resulting surface is an inhibited surface. In some embodiments, the first surface is a functionalized surface, wherein the functionalized surface comprises functional groups configured to react with the Al-containing inhibitor compound. In some embodiments, the first surface comprises hydroxyl groups. In some embodiments, the functional groups are exposed or otherwise available for reaction with or accessible to the Al-containing inhibitor compound. In some embodiments, the functionalized surface comprises functional groups configured to react with alkyls of the Al-containing inhibitor compound. In some embodiments, the functional groups of the functionalized surface comprise a plurality of hydroxyl groups. As appropriate, the functional groups may include functional groups other than, or in addition to, hydroxyl groups.

In some embodiments, the second surface is a surface on which a substance is to be deposited. In some embodiments, the substance to be deposited on the second surface is deposited by a deposition process, such as, any one or more of the deposition processes disclosed herein. For example, in some embodiments, the substance to be deposited on the second surface is a precursor for area selective deposition deposited during atomic layer deposition and/or chemical vapor deposition. In some embodiments, the second surface is a surface that is not inhibited by the Al-containing inhibitor compound. In some embodiments, the second surface is a surface that is not reactive with the Al-containing inhibitor compound. In some embodiments, the second surface is a functionalized surface, wherein the functional groups on the functionalized surface are not reactive with the Al-containing inhibitor compound. In some embodiments, the second surface does not comprise hydroxyl groups. In some embodiments, the second surface does not comprise hydroxyl groups exposed or otherwise available for reaction with or accessible to the Al-containing inhibitor compound.

The substrate may have more than the first surface and the second surface. In addition, the substrate may comprise at least one of a dielectric material, an insulating material, a conducting material, or any combination thereof. In some embodiments, the first surface of the substrate is constructed of or comprises at least one of a dielectric material, an insulating material, a conducting material, or any combination thereof. In some embodiments, the second surface of the substrate is constructed of or comprises at least one of a dielectric material, an insulating material, a conducting material, or any combination thereof. In some embodiments, the substrate comprises at least one of Si, Co, Cu, Al, W, WN, WC, TiN, Mo, MoC, SiO₂, SiOC, Ge, SiN, WCN, Al₂O₃, AlN, ZrO₂, La₂O₃, TaN, RuO₂, IrO₂, Nb₂O₃, Y₂O₃, hafnium oxide, or any combination thereof. In some embodiments, the substrate comprises other silicon-based substrates, such as, for example, one or more of polysilicon substrates, metallic substrates, and dielectric substrates. In some embodiments, at least one of the first surface, the second surface, or any combination thereof, comprises a metal. In some embodiments, at least one of the first surface, the second surface, or any combination thereof, is a metal surface. In some embodiments, at least one of the first surface, the second surface, or any combination thereof, is a non-metal surface. In some embodiments, at least one of the first surface, the second surface, or any combination thereof, does not comprise a metal.

At step 104, the method for selective deposition 100 comprises treating at least one of the first surface, the second surface, or any combination thereof.

The first surface of the substrate may be subjected to various treatments. For example, when the first surface of the substrate is not configured to be inhibited by the Al-containing inhibitor compound (e.g., when the first surface does not have hydroxyl groups), in some embodiments, the method may comprise functionalizing the first surface of the substrate. In some embodiments, the functionalizing comprises forming functional groups on the first surface of the substrate. In some embodiments, for example, the functionalizing comprises forming hydroxyl groups on the first surface of the substrate. In some embodiments, the functionalizing comprises surface hydroxyl functionalization. In some embodiments, the functionalizing comprising exposing the first surface to plasma (e.g., H₂/O₂ plasma treatment) so as to form hydroxyl groups on the first surface. In some embodiments, the functionalizing comprises contacting the first surface with a solvent so as to form hydroxyl groups on the first surface. In some embodiments, the functionalizing comprises contacting the first surface with anhydrous peroxide so as to form hydroxyl groups on the first surface. In some embodiments, the functionalizing comprises exposing the first surface to water vapor so as to form hydroxyl groups on the first surface. It will be appreciated that any techniques known in the art for functionalizing a surface may be employed herein, without departing from the scope of this disclosure. In some embodiments, the functionalizing does not comprise functionalizing the second surface of the substrate.

The second surface may be subjected to various treatments. In some embodiments, the method for selective deposition 100 comprises removing functional groups from the second surface of the substrate, such that, the second surface is not configured to be inhibited. In some embodiments, the removing comprises contacting the second surface of the substrate with a solvent to remove functional groups that are reactive with the Al-containing inhibitor compound. In some embodiments, the removing comprises exposing the second surface to a reactive gas and/or reactive vapor to remove functional groups that are reactive with the Al-containing inhibitor compound. In some embodiments, the method for selective deposition 100 comprises functionalizing the second surface of the substrate, such that, the second surface is not configured to be inhibited. In some embodiments, the functionalizing comprises functionalizing the second surface of the substrate, such that, the second surface is not reactive with the Al-containing inhibitor compound. In some embodiments, the functionalizing comprises functionalizing the second surface of the substrate with functional groups other than hydroxyl groups.

At step 106, the method for selective deposition 100 comprises exposing the substrate to an Al-containing inhibitor to modify the first surface.

In some embodiments, the exposing comprises contacting the substrate with the Al-containing inhibitor compound. In some embodiments, the contacting refers to bringing the substrate and the Al-containing inhibitor compound into close or immediate proximity. In some embodiments, the contacting refers to bringing the substrate and the Al-containing inhibitor compound into directly physical contact. In some embodiments, the exposing comprises reacting the Al-containing inhibitor compound with hydroxyl groups on the first surface. In some embodiments, the exposing does not comprise reacting the Al-containing inhibitor compound with the second surface. In some embodiments, the exposing comprises introducing the Al-containing inhibitor compound into a chamber containing the substrate. In some embodiments, the exposing comprises pumping the Al-containing inhibitor compound from one location to a chamber containing the substrate. In some embodiments, the exposing comprises supplying the Al-containing inhibitor compound to the substrate. In some embodiments, the exposing comprises vaporizing the Al-containing inhibitor compound. In some embodiments, the exposing comprises flowing the Al-containing inhibitor compound from one location to a chamber containing the substrate. In some embodiments, the exposing comprises feeding the Al-containing inhibitor compound to a chamber containing the substrate. In some embodiments, exposing the substrate to the Al-containing inhibitor compound comprises pulsing the Al-containing inhibitor compound into a chamber containing the substrate.

In some embodiments, the exposing proceeds at a temperature of 100° C. to 400° C., or any range or subrange between 100° C. to 400° C. In some embodiments, the temperature is a temperature in a range of 100° C. to 380° C., 100° C. to 360° C., 100° C. to 340° C., 100° C. to 320° C., 100° C. to 300° C., 100° C. to 280° C., 100° C. to 260° C., 100° C. to 240° C., 100° C. to 220° C., 100° C. to 200° C., 100° C. to 180° C., 100° C. to 160° C., 100° C. to 140° C., or 100° C. to 120° C. In some embodiments, the temperature is a temperature in a range of 120° C. to 400° C., 140° C. to 400° C., 160° C. to 400° C., 180° C. to 400° C., 200° C. to 400° C., 220° C. to 400° C., 240° C. to 400° C., 260° C. to 400° C., 280° C. to 400° C., 300° C. to 400° C., 320° C. to 400° C., 340° C. to 400° C., 360° C. to 400° C., or 380° C. to 400° C.

In some embodiments, the exposing proceeds at a pressure of 0.1 Torr to 50 Torr, or any range or subrange between therebetween. In some embodiments, the pressure is a pressure in a range of 0.1 Torr to 45 Torr, 0.1 Torr to 40 Torr, 0.1 Torr to 35 Torr, 0.1 Torr to 30 Torr, 0.1 Torr to 25 Torr, 0.1 Torr to 20 Torr, 0.1 Torr to 15 Torr, 0.1 Torr to 10 Torr, 0.1 Torr to 5 Torr, 0.1 Torr to 1 Torr, 0.1 Torr to 0.2 Torr, 0.1 Torr to 50 Torr, 0.2 Torr to 50 Torr, 5 Torr to 50 Torr, 10 Torr to 50 Torr, 15 Torr to 50 Torr, 20 Torr to 50 Torr, 25 Torr to 50 Torr, 30 Torr to 50 Torr, 35 Torr to 50 Torr, 40 Torr to 50 Torr, or 45 Torr to 50 Torr.

In some embodiments, the Al-containing inhibitor compound comprises a compound of the formula:

Q-Al—(R)₂,
where:
Q comprises a cyclopentadienyl or an indenyl; and
R independently comprises an alkyl.

In some embodiments, the cyclopentadienyl comprises a substituted cyclopentadienyl. In some embodiments, the cyclopentadienyl comprises one (1) to four (4) substituents. In some embodiments, the substituted cyclopentadienyl comprises at least one of an alkyl cyclopentadienyl, a fluorinated cyclopentadienyl, or any combination thereof. In some embodiments, when the cyclopentadienyl comprises a fluorinated cyclopentadienyl, the cyclopentadienyl is substituted with at least one fluoroalkyl. In some embodiments, the fluoroalkyl comprises at least one of —CH₂CF₃, —CH(CF₃)₂, —CH₂F, —CH₂CH₂F, —CF₃, —CF₂CF₃, or any combination thereof.

In some embodiments, the cyclopentadienyl comprises an unsubstituted cyclopentadienyl.

In some embodiments, the indenyl comprise a substituted indenyl. In some embodiments, the indenyl comprises one (1) to seven (7) substituents. In some embodiments, the substituted indenyl comprises at least one of an alkyl indenyl, a fluorinated indenyl, or any combination thereof. In some embodiments, when the indenyl comprises a fluorinated indenyl, the indenyl is substituted with at least one fluoroalkyl. In some embodiments, the fluoroalkyl comprises at least one of —CH₂CF₃, —CH(CF₃)₂, —CH₂F, —CH₂CH₂F, —CF₃, —CF₂CF₃, or any combination thereof.

In some embodiments, the indenyl comprises an unsubstituted indenyl.

In some embodiments, the Al-containing inhibitor compound comprises a cyclopentadienyl and a C₁-C₅ alkyl. In some embodiments, the Al-containing inhibitor compound comprises a substituted cyclopentadienyl and a C₁-C₅ alkyl. In some embodiments, the Al-containing inhibitor compound comprises an alkyl cyclopentadienyl and a C₁-C₅ alkyl. In some embodiments, the Al-containing inhibitor compound comprises a fluorinated cyclopentadienyl and a C₁-C₅ alkyl. In some embodiments, the Al-containing inhibitor compound comprises an unsubstituted cyclopentadienyl and a C₁-C₅ alkyl.

In some embodiments, the Al-containing inhibitor compound comprises a indenyl and a C₁-C₅ alkyl. In some embodiments, the Al-containing inhibitor compound comprises a substituted indenyl and a C₁-C₅ alkyl. In some embodiments, the Al-containing inhibitor compound comprises an alkyl indenyl and a C₁-C₅ alkyl. In some embodiments, the Al-containing inhibitor compound comprises a fluorinated indenyl and a C₁-C₅ alkyl. In some embodiments, the Al-containing inhibitor compound comprises an unsubstituted indenyl and a C₁-C₅ alkyl.

In some embodiments, the Al-containing inhibitor compound comprises a compound of the formula:

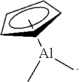

At step 108, the method for selective deposition 100 comprises selectively 106 depositing a film on the second surface.

In some embodiments, the film is deposited on the second surface of the substrate. In some embodiments, the depositing does not comprise depositing the film on the first surface. In some embodiments, the film is deposited on the second surface of the substrate via a vapor deposition process. For example, in some embodiments, the depositing comprises vaporizing a precursor to obtain a vaporized precursor. The vaporizing may comprise heating the precursor sufficient to obtain the vaporized precursor. In some embodiments, the vaporizing comprises heating a container comprising the precursor. In some embodiments, the vaporizing comprises heating the precursor in a deposition chamber in which the vapor deposition process is performed. In some embodiments, the vaporizing comprises heating a conduit for delivering the precursor, the vaporized precursor, or any combination thereof to, for example, a deposition chamber. In some embodiments, the vaporizing comprises operating a vapor delivery system comprising the precursor. In some embodiments, the vaporizing comprises heating to a temperature sufficient to vaporize the precursor to obtain the vaporized precursor. In some embodiments, the vaporizing comprises heating to a temperature below a decomposition temperature of at least one of the precursor, the vaporized precursor, or any combination thereof. In some embodiments, the precursor may be present in a gas phase or other vaporizable phase, in which case the vaporizing is optional and not required. For example, in some embodiments, the precursor comprises the vaporized precursor.

In some embodiments, the depositing comprises vaporizing at least one co-reactant precursor c to obtain at least one vaporized co-reactant precursor. In some embodiments, the vaporizing comprises heating the at least one co-reactant precursor sufficient to obtain the at least one vaporized co-reactant precursor. In some embodiments, the vaporizing comprises heating a container comprising the at least one co-reactant precursor. In some embodiments, the vaporizing comprises heating the at least one co-reactant precursor in a deposition chamber in which the vapor deposition process is performed. In some embodiments, the vaporizing comprises heating a conduit for delivering the at least one co-reactant precursor, the at least one vaporized co-reactant precursor, or any combination thereof to, for example, a deposition chamber. In some embodiments, the vaporizing comprises operating a vapor delivery system comprising the at least one co-reactant precursor. In some embodiments, the vaporizing comprises heating to a temperature sufficient to vaporize the at least one co-reactant precursor to obtain the at least one vaporized co-reactant precursor. In some embodiments, the vaporizing comprises heating to a temperature below a decomposition temperature of at least one of the at least one co-reactant precursor, the at least one vaporized co-reactant precursor, or any combination thereof. In some embodiments, the at least one co-reactant precursor may be present in a gas phase or other vaporizable phase, in which case the vaporizing is optional and not required. For example, in some embodiments, the at least one co-reactant precursor comprises the at least one vaporized co-reactant precursor.

In some embodiments, the depositing comprises exposing, under vapor deposition conditions, the substrate to at least one of the vaporized precursor, the at least one vaporized co-reactant precursor, or any combination thereof, to form a film on the first surface of substrate. The exposing may be performed in any system, apparatus, device, assembly, chamber thereof, or component thereof suitable for vapor deposition processes, including, for example and without limitation, a deposition chamber, among others. In some embodiments, the exposing comprises contacting the substrate with at least one of the vaporized precursor, the at least one vaporized co-reactant precursor, or any combination thereof. The vaporized precursor and the at least one co-reactant precursor may be contacted with the substrate at the same time or at different times. For example, each of the vaporized precursor, the at least one vaporized co-reactant precursor, and the substrate may be present in the deposition chamber at the same time. That is, in some embodiments, the contacting may comprise contemporaneous contacting or simultaneous contacting of the vaporized precursor and the at least one vaporized co-reactant precursor with the substrate. Alternatively, each of the vaporized precursor and the at least one vaporized co-reactant precursor may be present in the deposition chamber at different times. That is, in some embodiments, the contacting may comprise alternate and/or sequential contacting, in one or more cycles, of the vaporized precursor with the substrate and subsequently contacting the at least one vaporized co-reactant precursor with the substrate.

The vapor deposition conditions may comprise conditions for vapor deposition processes, including selective area deposition during vapor deposition processes. Examples of vapor deposition conditions include, without limitation, vapor deposition conditions for vapor deposition processes including at least one of a chemical vapor deposition (CVD) process, a digital or pulsed chemical vapor deposition process, a plasma-enhanced cyclical chemical vapor deposition process (PECCVD), a flowable chemical vapor deposition process (FCVD), an atomic layer deposition (ALD) process, a thermal atomic layer deposition, a plasma-enhanced atomic layer deposition (PEALD) process, a metal organic chemical vapor deposition (MOCVD) process, a plasma-enhanced chemical vapor deposition (PECVD) process, or any combination thereof.

The vapor deposition conditions may comprise a deposition temperature. The deposition temperature may be a temperature less than the thermal decomposition temperature of at least one of the vaporized precursor, the at least one vaporized co-reactant precursor, or any combination thereof. The deposition temperature may be sufficiently high to reduce or avoid condensation of at least one of the vaporized precursor, the at least one vaporized co-reactant precursor, or any combination thereof. In some embodiments, the substrate may be heated to the deposition temperature. In some embodiments, the chamber or other vessel in which the substrate is contacted with the vaporized precursor and the at least one vaporized co-reactant precursor is heated to the deposition temperature. In some embodiments, at least one of the vaporized precursor, the at least one vaporized co-reactant precursor, or any combination thereof may be heated to the deposition temperature.

The deposition temperature may be a temperature of 200° C. to 2500° C., or any range or subrange between 200° C. and 2500° C. In some embodiments, the deposition temperature may be a temperature of 500° C. to 700° C. For example, in some embodiments, the deposition temperature may be a temperature of 500° C. to 680° C., 500° C. to 660° C., 500° C. to 640° C., 500° C. to 620° C., 500° C. to 600° C., 500° C. to 580° C., 500° C. to 560° C., 500° C. to 540° C., 500° C. to 520° C., 520° C. to 700° C., 540° C. to 700° C., 560° C. to 700° C., 580° C. to 700° C., 600° C. to 700° C., 620° C. to 700° C., 640° C. to 700° C., 660° C. to 700° C., or 680° C. to 700° C. In other embodiments, the deposition temperature may be a temperature of greater than 200° C. to 2500° C., such as, for example and without limitation, a temperature of 400° C. to 2000, 500° C. to 2000° C., 550° C. to 2400° C., 600° C. to 2400° C., 625° C. to 2400° C., 650° C. to 2400° C., 675° C. to 2400° C., 700° C. to 2400° C., 725° C. to 2400° C., 750° C. to 2400° C., 775° C. to 2400° C., 800° C. to 2400° C., 825° C. to 2400° C., 850° C. to 2400° C., 875° C. to 2400° C., 900° C. to 2400° C., 925° C. to 2400° C., 950° C. to 2400° C., 975° C. to 2400° C., 1000° C. to 2400° C., 1025° C. to 2400° C., 1050° C. to 2400° C., 1075° C. to 2400° C., 1100° C. to 2400° C., 1200° C. to 2400° C., 1300° C. to 2400° C., 1400° C. to 2400° C., 1500° C. to 2400° C., 1600° C. to 2400° C., 1700° C. to 2400° C., 1800° C. to 2400° C., 1900° C. to 2400° C., 2000° C. to 2400° C., 2100° C. to 2400° C., 2200° C. to 2400° C., 2300° C. to 2400° C., 500° C. to 2000° C., 500° C. to 1900° C., 500° C. to 1800° C., 500° C. to 1700° C., 500° C. to 1600° C., 500° C. to 1500° C., 500° C. to 1400° C., 500° C. to 1300° C., 500° C. to 1200° C., 500° C. to 1100° C., 500° C. to 1000° C., 500° C. to 1000° C., 500° C. to 900° C., or 500° C. to 800° C.

The vapor deposition conditions may comprise a deposition pressure. In some embodiments, the deposition pressure may comprise a vapor pressure of at least one of the vaporized precursor, the at least one vaporized co-reactant precursor, or any combination thereof. In some embodiments, the deposition pressure may comprise a chamber pressure.

The deposition pressure may be a pressure of 0.001 Torr to 100 Torr, or any range or subrange between 0.001 Torr and 100 Torr. For example, in some embodiments, the deposition pressure may be a pressure of 1 Torr to 30 Torr, 1 Torr to 25 Torr, 1 Torr to 20 Torr, 1 Torr to 15 Torr, 1 Torr to 10 Torr, 5 Torr to 50 Torr, 5 Torr to 40 Torr, 5 Torr to 30 Torr, 5 Torr to 20 Torr, or 5 Torr to 15 Torr. In other embodiments, the deposition pressure may be a pressure of 1 Torr to 100 Torr, 5 Torr to 100 Torr, 10 Torr to 100 Torr, 15 Torr to 100 Torr, 20 Torr to 100 Torr, 25 Torr to 100 Torr, 30 Torr to 100 Torr, 35 Torr to 100 Torr, 40 Torr to 100 Torr, 45 Torr to 100 Torr, 50 Torr to 100 Torr, 55 Torr to 100 Torr, 60 Torr to 100 Torr, 65 Torr to 100 Torr, 70 Torr to 100 Torr, 75 Torr to 100 Torr, 80 Torr to 100 Torr, 85 Torr to 100 Torr, 90 Torr to 100 Torr, 95 Torr to 100 Torr, 1 Torr to 95 Torr, 1 Torr to 90 Torr, 1 Torr to 85 Torr, 1 Torr to 80 Torr, 1 Torr to 75 Torr, or 1 Torr to 70 Torr. In other further embodiments, the deposition pressure may be a pressure of 1 mTorr to 100 mTorr, 1 mTorr to 90 mTorr, 1 mTorr to 80 mTorr, 1 mTorr to 70 mTorr, 1 mTorr to 60 mTorr, 1 mTorr to 50 mTorr, 1 mTorr to 40 mTorr, 1 mTorr to 30 mTorr, 1 mTorr to 20 mTorr, 1 mTorr to 10 mTorr, 100 mTorr to 300 mTorr, 150 mTorr to 300 mTorr, 200 mTorr to 300 mTorr, or 150 mTorr to 250 mTorr, or 150 mTorr to 225 mTorr.

The precursor may comprise at least one of at least one of dimethyl hydrazine, trimethyl aluminum (TMA), hafnium chloride (HfCl₄), zirconium chloride (ZrCl₄), indium trichloride, indium monochloride, aluminum trichloride, titanium iodide, tungsten carbonyl, Ba(DPM)₂, bis dipivaloyl methanato strontium (Sr(DPM)₂), TiO(DPM)₂, tetra dipivaloyl methanato zirconium (Zr(DPM)₄), decaborane, octadecaborane, boron, magnesium, gallium, indium, antimony, copper, phosphorous, arsenic, lithium, sodium tetrafluoroborates, precursors incorporating alkyl-amidinate ligands, organometallic precursors, zirconium tertiary butoxide (Zr(t-OBu)₄), tetrakisdiethylaminozirconium (Zr(Net₂)₄), tetrakisdiethylaminohafnium (Hf(Net₂)₄), tetrakis(dimethylamino)titanium (TDMAT), tertbutyliminotris(diethylamino)tantalum (TBTDET), pentakis(dimethylamino)tantalum (PDMAT), pentakis(ethylmethylamino)tantalum (PEMAT), tetrakisdimethylaminozirconium (Zr(NMe₂)₄), hafniumtertiarybutoxide (Hf(tOBu)₄), xenon difluoride (XeF₂), xenon tetrafluoride (XeF₄), xenon hexafluoride (XeF₆), or any combination thereof.

In some embodiments, the precursor comprises at least one of decaborane, hafnium tetrachloride, zirconium tetrachloride, indium trichloride, metalorganic β-diketonate complexes, tungsten hexafluoride, cyclopentadienylcycloheptatrienyl-titanium (CpTiCht), aluminum trichloride, titanium iodide, cyclooctatetraenecyclo-pentadienyltitanium, biscyclopentadienyltitaniumdiazide, trimethyl gallium, trimethyl indium, aluminum alkyls like trimethylaluminum, triethylaluminum, trimethylamine alane, dimethyl zinc, tetramethyl tin, trimethyl antimony, diethyl cadmium, tungsten carbonyl, or any combination thereof.

In some embodiments, the precursor comprises at least one of elemental metal, metal halides, metal oxyhalides, metalorganic complexes, or any combination thereof. For example, in some embodiments, the precursor comprises at least one of elemental boron, copper, phosphorus, decaborane, gallium halides, indium halides, antimony halides, arsenic halides, gallium halides, aluminum iodide, titanium iodide, MoO₂Cl₂, MoOCl₄, MoCl₅, WCl₅, WOCl₄, WCl₆, cyclopentadienylcycloheptatrienyltitanium (CpTiCht), cyclooctatetraenecyclopenta-dienyltitanium, biscyclopentadienyltitanium-diazide, In(CH₃)₂(hfac), dibromomethyl stibine, tungsten carbonyl, metalorganic β-diketonate complexes, metalorganic alkoxide complexes, metalorganic carboxylate complexes, metalorganic aryl complexes, metalorganic amido complexes, or any combination thereof.

In some embodiments, the precursor comprises at least one of any type of source material that can be liquefied either by heating or solubilization in a solvent including, for example and without limitation, at least one of decaborane, (B₁₀H1₄), pentaborane (B₅H₉), octadecaborane (B1₈H₂₂), boric acid (H₃BO₃), SbCl₃, SbCl₅, or any combination thereof.

In some embodiments, the precursor comprises at least one of at least one of AsC₃, AsBr₃, AsF₃, AsF₅, AsH₃, As₄O₆, As₂Se₃m As₂S₂, As₂S₃, As₂S₅, As₂Te₃, B₄H₁₁, B₄H₁₀, B₃H₆N₃, BBr₃, BCl₃, BF₃, BF₃·O(C₂H₅)₂, BF₃·HOCH₃, B₂H₆, F₂, HF, GeBr₄, GeCl₄, GeF₄, GeH₄, H₂, HCl, H₂Se, H₂Te, H₂S, WF₆, SiH₄, SiH₂Cl₂, SiHCl₃, SiC₄, SiH₃Cl, NH₃, NH₃, Ar, Br₂, HBr, BrF₅, CO₂, CO, COCl₂, COF₂, Cl₂, CIF₃, CF₄, C₂F₆, C₃F₈, C₄F₈, C₅F₈, CHF₃, CH₂F₂, CH₃F, CH₄, SiH₆, He, HCN, Kr, Ne, Ni(CO)₄, HNO₃, NO, N₂, NO₂, NF₃, N₂O, C₈H₂₄O₄Si₄, PH₃, POCl₃, PCI₅, PF₃, PFS, SbH₃, SO₂, SF₆, SF₄, Si(OC₂H₅)₄, C₄H1₆Si₄O₄, Si(CH₃)₄, SiH(CH₃)₃, TiCl₄, Xe, SiF₄, WOF₄, TaBr₅, TaCl₅, TaF₅, Sb(C₂H₅)₃, Sb(CH₃)₃, In(CH₃)₃, PBr₅, PBr₃, RuF₅, or any combination thereof.

The at least one co-reactant precursor may comprise at least one of an oxidizing gas, a reducing gas, a hydrocarbon, or any combination thereof. The at least one co-reactant precursor may be selected to obtain a desired film. In some embodiments, the at least one co-reactant precursor comprises at least one of N₂, H₂, NH₃, N₂H₄, CH₃HNNH₂, CH₃HNNHCH₃, NCH₃H₂, NCH₃CH₂H₂, N(CH₃)₂H, N(CH₃CH₂)₂H, N(CH₃)₃, N(CH₃CH₂)₃, Si(CH₃)₂NH, pyrazoline, pyridine, ethylene diamine, a radical thereof, or any combination thereof. In some embodiments, the at least one co-reactant precursor comprises at least one of H₂, O₂, O₃, H₂O, H₂O₂, NO, N₂O, NO₂, CO, CO₂, a carboxylic acid, an alcohol, a diol, a radical thereof, or any combination thereof. In some embodiments, the at least one co-reactant precursor comprises at least one of methane, ethane, ethylene, acetylene, or any combination thereof. The obtaining may comprise obtaining a container or other vessel comprising the at least one co-reactant precursor. In some embodiments, the at least one co-reactant precursor may be obtained in a container or other vessel in which the at least one co-reactant precursor is to be vaporized. In some embodiments, the method further comprises an inert gas, such as, for example, at least one of argon, helium, nitrogen, or any combination thereof.

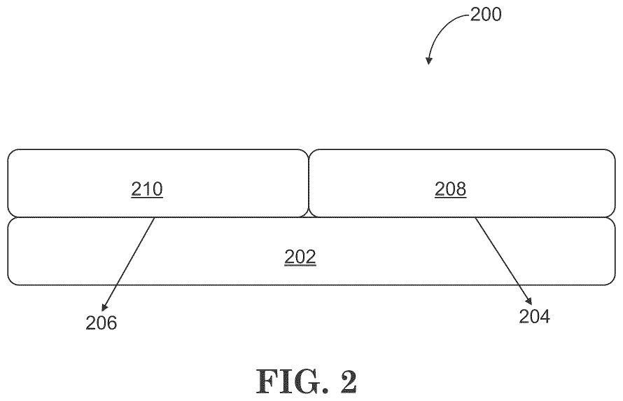

FIG. 2 is a schematic diagram of a cross-sectional view of a device 200, according to some embodiments. As shown in FIG. 2, the device 200 comprises a substrate 202. In some embodiments, the substrate 202 has a first surface 204 and a second surface 206. In some embodiments, an Al-containing inhibitor 208 is deposited on the first surface 204. In some embodiments, a film 210 is deposited on the second surface 206. In some embodiments, the film 210 is not deposited on the first surface 204.

Some embodiments relate to a composition. In some embodiments, the composition comprises an Al-containing inhibitor compound. In some embodiments, the Al-containing inhibitor compound comprises a compound of the formula:

Q-Al—(R)₂,
where:
Q comprises a cyclopentadienyl or an indenyl; and
R independently comprises an alkyl.

In some embodiments, the cyclopentadienyl comprises a substituted cyclopentadienyl. In some embodiments, the substituted cyclopentadienyl comprises at least one of an alkyl cyclopentadienyl, a fluorinated cyclopentadienyl, or any combination thereof.

In some embodiments, the cyclopentadienyl comprises an unsubstituted cyclopentadienyl.

In some embodiments, the indenyl comprise a substituted indenyl. In some embodiments, the substituted indenyl comprises at least one of an alkyl indenyl, a fluorinated indenyl, or any combination thereof.

In some embodiments, the indenyl comprises an unsubstituted indenyl.

In some embodiments, the Al-containing inhibitor compound comprises a cyclopentadienyl and a C₁-C₅ alkyl. In some embodiments, the Al-containing inhibitor compound comprises a substituted cyclopentadienyl and a C₁-C₅ alkyl. In some embodiments, the Al-containing inhibitor compound comprises an alkyl cyclopentadienyl and a C₁-C₅ alkyl. In some embodiments, the Al-containing inhibitor compound comprises a fluorinated cyclopentadienyl and a C₁-C₅ alkyl. In some embodiments, the Al-containing inhibitor compound comprises an unsubstituted cyclopentadienyl and a C₁-C₅ alkyl.

In some embodiments, the Al-containing inhibitor compound comprises a indenyl and a C₁-C₅ alkyl. In some embodiments, the Al-containing inhibitor compound comprises a substituted indenyl and a C₁-C₅ alkyl. In some embodiments, the Al-containing inhibitor compound comprises an alkyl indenyl and a C₁-C₅ alkyl. In some embodiments, the Al-containing inhibitor compound comprises a fluorinated indenyl and a C₁-C₅ alkyl. In some embodiments, the Al-containing inhibitor compound comprises an unsubstituted indenyl and a C₁-C₅ alkyl.

In some embodiments, the Al-containing inhibitor compound comprises a compound of the formula:

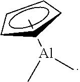

In some embodiments, the Al-containing inhibitor compound is present in the composition at a purity of at least 95%. In some embodiments, the Al-containing inhibitor compound is present in the composition at a purity of 95% to 99.9999%, 95% to 99.999%, 95% to 99.99%, 95% to 99.9%, 95% to 99%, 95% to 98%, 95% to 97%, 95% to 96%, 96% to 99.9999%, 97% to 99.9999%, 98% to 99.9999%, 99% to 99.9999%, 99.9% to 99.9999%, 99.99% to 99.9999%, 99.999% to 99.9999%, or any range or subrange between 95% and 99.9999%.

Any one or more of the embodiments disclosed herein shall be understood to be combinable without departing from the scope or spirit of the disclosure.

### EXAMPLES

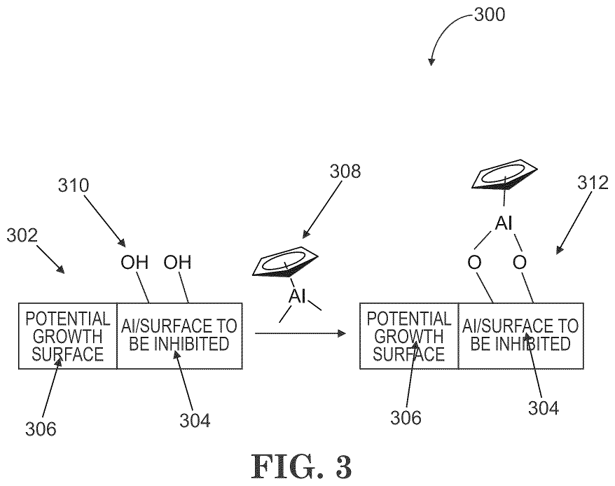

FIG. 3 is a schematic diagram of a method for selective deposition, according to some embodiments. As shown in FIG. 3, a substrate 302 having a first surface 304 and a second surface 306 was exposed to an aluminum-containing inhibitor compound 308 of the formula:

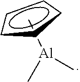

The first surface 304 had exposed hydroxyl groups 310, whereas the second surface 306 did not have any exposed hydroxyl groups. After exposing the substrate 302 to the aluminum-containing inhibitor compound 308, the hydroxyl groups 310 on the first surface 304 reacted with the aluminum-containing inhibitor compound 308 to form an inhibited surface 312.

### ASPECTS

Various Aspects are described below. It is to be understood that any one or more of the features recited in the following Aspect(s) can be combined with any one or more other Aspect(s).
Aspect 1. A method comprising:
   obtaining a substrate having a first surface and a second surface;
   exposing the substrate to an Al-containing inhibitor to modify the first surface,
      wherein the Al-containing inhibitor is a compound comprising a substituted aluminum alkyl; and
   selectively depositing a film on the second surface.
Aspect 2. The method according to Aspect 1, wherein the first surface has hydroxyl groups and wherein the second surface does not have hydroxyl groups.
Aspect 3. The method according to any one of Aspects 1-2, wherein the exposing comprises reacting the Al-containing inhibitor with hydroxyl groups on the first surface.
Aspect 4. The method according to any one of Aspects 1-2, wherein the exposing does not comprise the Al-containing inhibitor reacting with the second surface.
Aspect 5. The method according to any one of Aspects 1-4, further comprising, prior to the step of exposing, forming hydroxyl groups on the first surface of the substrate.
Aspect 6. The method according to any one of Aspects 1-5, wherein the Al-containing inhibitor comprises a compound of the formula:

Q-Al—(R)₂,
where:
   Q is a cyclopentadienyl or an indenyl; and
   R is independently an alkyl.
Aspect 7. The method according to Aspect 6, wherein the cyclopentadienyl comprises a substituted cyclopentadienyl.
Aspect 8. The method according to Aspect 7, wherein the substituted cyclopentadienyl comprises at least one of an alkyl cyclopentadienyl, a fluorinated cyclopentadienyl, or any combination thereof.
Aspect 9. The method according to Aspect 6, wherein the indenyl comprises a substituted indenyl.
Aspect 10. The method according to Aspect 9, wherein the substituted indenyl comprises at least one of an alkyl indenyl, a fluorinated indenyl, or any combination thereof.
Aspect 11. The method according to Aspect 6, wherein the cyclopentadienyl comprises an unsubstituted cyclopentadienyl or an unsubstituted indenyl.
Aspect 12. The method according to Aspect 6, wherein the alkyl comprises a C₁-C₅ alkyl.
Aspect 13. The method according to any one of Aspects 1-12, wherein the Al-containing inhibitor comprises a compound of the formula:

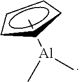

Aspect 14. The method according to any one of Aspects 1-13, wherein selectively depositing the film does not comprise depositing the film on the first surface.
Aspect 15. A composition comprising:
   an Al-containing inhibitor comprising a compound of the formula:

Q-Al—(R)₂,
where:
   Q is a cyclopentadienyl or an indenyl; and
   R is independently an alkyl;
wherein, when the Al-containing inhibitor is exposed to a substrate having a first surface with hydroxyl groups and a second surface without hydroxyl groups, the Al-containing inhibitor modifies the first surface sufficient for a film to be selectively deposited on the second surface.
Aspect 16. The composition according to Aspect 15, wherein the cyclopentadienyl comprises a substituted cyclopentadienyl or a substituted indenyl.
Aspect 17. The composition according to Aspect 16, wherein the substituted cyclopentadienyl comprises at least one of an alkyl cyclopentadienyl, a fluorinated cyclopentadienyl, or any combination thereof.
Aspect 18. The composition according to Aspect 16, wherein the substituted indenyl comprises at least one of an alkyl indenyl, a fluorinated indenyl, or any combination thereof.
Aspect 19. The composition according to any one of Aspects 15-18, wherein the alkyl comprises a C₁-C₅ alkyl.
Aspect 20. The composition according to any one of Aspects 15-19, wherein the Al-containing inhibitor comprises a compound of the formula:

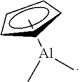

Aspect 21. A device comprising:
   a film;
   an Al-containing inhibitor; and
   a substrate having at least a first surface and a second surface,
      wherein the Al-containing inhibitor is deposited on the first surface;
      wherein the film is not deposited on the first surface;
      wherein the film is deposited on the second surface.

What is claimed is:

1. A method comprising:
obtaining a substrate having a first surface and a second surface;
exposing the substrate to an Al-containing inhibitor to modify the first surface, wherein the Al-containing inhibitor is a compound comprising a substituted aluminum alkyl; and
selectively depositing a film on the second surface.

2. The method of claim 1, wherein the first surface has hydroxyl groups and wherein the second surface does not have hydroxyl groups.

3. The method of claim 2, wherein the exposing comprises reacting the Al-containing inhibitor with hydroxyl groups on the first surface.

4. The method of claim 2, wherein the exposing does not comprise the Al-containing inhibitor reacting with the second surface.

5. The method of claim 1, further comprising, prior to the step of exposing, forming hydroxyl groups on the first surface of the substrate.

6. The method of claim 1, wherein the Al-containing inhibitor comprises a compound of the formula:
Q-Al—(R)₂,
where:
Q is a cyclopentadienyl or an indenyl; and
R is independently an alkyl.

7. The method of claim 6, wherein the cyclopentadienyl comprises a substituted cyclopentadienyl.

8. The method of claim 7, wherein the substituted cyclopentadienyl comprises at least one of an alkyl cyclopentadienyl, a fluorinated cyclopentadienyl, or any combination thereof.

9. The method of claim 6, wherein the indenyl comprises a substituted indenyl.

10. The method of claim 9, wherein the substituted indenyl comprises at least one of an alkyl indenyl, a fluorinated indenyl, or any combination thereof.

11. The method of claim 6, wherein the cyclopentadienyl comprises an unsubstituted cyclopentadienyl or an unsubstituted indenyl.

12. The method of claim 6, wherein the alkyl comprises a C₁-C₅ alkyl.

13. The method of claim 1, wherein the Al-containing inhibitor comprises a compound of the formula:

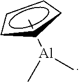

14. The method of claim 1, wherein selectively depositing the film does not comprise depositing the film on the first surface.

15. A composition comprising:
an Al-containing inhibitor comprising a compound of the formula:
Q-Al—(R)₂,
where:
Q is a cyclopentadienyl or an indenyl; and
R is independently an alkyl;
wherein, when the Al-containing inhibitor is exposed to a substrate having a first surface with hydroxyl groups and a second surface without hydroxyl groups, the Al-containing inhibitor modifies the first surface sufficient for a film to be selectively deposited on the second surface.

16. The composition of claim 15, wherein the cyclopentadienyl comprises a substituted cyclopentadienyl or a substituted indenyl.

17. The composition of claim 16, wherein the substituted cyclopentadienyl comprises at least one of an alkyl cyclopentadienyl, a fluorinated cyclopentadienyl, or any combination thereof.

18. The composition of claim 16, wherein the substituted indenyl comprises at least one of an alkyl indenyl, a fluorinated indenyl, or any combination thereof.

19. The composition of claim 15, wherein the Al-containing inhibitor comprises a compound of the formula:

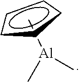

20. A device comprising:
a film;
an Al-containing inhibitor; and
a substrate having at least a first surface and a second surface,
wherein the Al-containing inhibitor is deposited on the first surface;
wherein the film is not deposited on the first surface;
wherein the film is deposited on the second surface.
